(19) United States
(12) Patent Application Publication
(10) Pub. No.: US 2004/0218434 A1
(43) Pub. Date: Nov. 4, 2004

(54) Mismatched on-die termination circuits and termination methods therefor

(76) Inventors: Sang-joon Hwang, Seoul (KR); Young-hyun Jun, Seoul (KR); Kyung-woo Kang, Gyeonggi-do (KR); Seong-jin Jang, Gyeonggi-do (KR)

Correspondence Address: MYERS BIGEL SIBLEY & SAJOVEC, PO BOX 37428, RALEIGH, NC, 27627, US

(21) Appl. No.: 10/832,891

(22) Filed: Apr. 27, 2004

(30) Foreign Application Priority Data
Apr. 29, 2003 (KR) 10-2003-27076

(51) Int. Cl. G11C 29/00

(52) U.S. Cl. 365/200

(57) ABSTRACT

Methods of terminating an external transmission line in a memory device having an on-die termination circuit include electrically coupling the termination circuit to the transmission line in response to a control signal which indicates that the memory device is in an active mode or a write mode. The termination circuit has an impedance value that is mismatched with an impedance value of the transmission line. The termination circuit can include an input/output pad, a resistor, and a transistor connected in series to a reference voltage. Also, the termination circuit may be electrically coupled to the transmission line by activating the transistor in the termination circuit to connect the transmission line to the reference voltage in response to the control signal. Related devices are also disclosed.

### CROSS-REFERENCE TO RELATED APPLICATION

This application claims priority under 35 U.S.C. § 119 from Korean Patent Application No. 2003-27076, filed Apr. 29, 2003, the contents of which are incorporated herein by reference in their entirety.

### BACKGROUND OF THE INVENTION

1. Field of the Invention

The present invention relates to semiconductor memory devices, and more particularly, to memory devices including on-die termination circuits and termination methods therefor.

2. Description of the Related Art

Modem computer systems may strive to efficiently utilize computer memory devices in ways which increase transmission speeds and optimize data transmission. As such, writing and reading information to and from high-speed memory devices, such as DRAMs, may be controlled by data transmission termination techniques.

As is well known in transmission line theory, non-terminated transmission lines on a receiving side may face double the voltage provided by a source driver on a transmitting side. The overvoltage is reflected on the receiving side, and is transferred back to the source driver via the transmission lines. To reduce such reflection, a transmission line can be terminated by a passive termination device with an impedance matched to the impedance of the transmission line. For example, if the impedance of the transmission line is 50-60 Ω, a passive termination device may consist of a resistor having an impedance of 50-60 Ω.

FIG. 1 illustrates a conventional passive termination circuit on a receiving side of the transmission line. Referring to FIG. 1, a receiving side 100 of a transmission line 102 includes passive termination devices, such as resistors R1 and R2, which have the same impedance as the impedance Z0 of the transmission line 102 in order to prevent reflection.

FIG. 2 illustrates a conventional passive termination circuit on a transmitting side of the transmission line. Referring to FIG. 2, a different passive termination device, such as resistor R3, on the transmitting side 104 of the transmission line 102 is connected in series to a source driver 106 in order to absorb reflection generated by a non-terminated receiving side 108.

Another known technique for controlling read/write operations in high-speed DRAM memory devices involves dividing DRAM memory devices into “ranks” which are turned on or off for data read/write operations via an active termination control signal. The active termination control signal can control which rank of memory is accessed. An “on” state of the active termination control signal may enable a specific DRAM memory device to be written to, and an “off” state of the active termination signal may enable a DRAM memory device to be read.

However, because the termination is always in an “on” state in the conventional circuits shown in FIGS. 1 and 2 and the above-described termination method which uses an active termination control signal, power consumption in the DRAM memory may be increased.

### SUMMARY OF THE INVENTION

According to embodiments of the present invention, a method of terminating an external transmission line in a memory device having an on-die termination circuit may include electrically coupling the termination circuit to the transmission line in response to a control signal which indicates that the memory device is in an active mode or a write mode. The termination circuit may have an impedance value that is mismatched with the impedance value of the transmission line.

For example, the termination circuit may include an input/output pad, a resistor, and a transistor connected in series to a reference voltage. The transistor may have an on-resistance value of about 100 Ω, the resistor may have a resistance of about 200 Ω, and the transmission line may have an impedance of about 50 to 60 Ω. The transistor can be an NMOS transistor or a PMOS transistor, and the reference voltage can be a ground voltage or a source voltage. Also, the input/output pad may be a DQ pad, a DQS pad, or a DM pad. The input/output pad may be connected to a pad of an external memory controller of the memory device using a point-to-point method.

In addition, electrically coupling the termination circuit to the transmission line may include activating the transistor in the termination circuit to connect the transmission line to the reference voltage in response to the control signal. The control signal can be generated by a fuse option or a signal option set in a mode register in the memory device.

According to further embodiments of the present invention, an integrated circuit memory device may include a transmission line and a termination circuit that is electrically coupled to the transmission line responsive to a control signal which indicates that the memory device is in an active mode or a write mode. The termination circuit may have an impedance value that is mismatched with the impedance value of the transmission line.

For example, the termination circuit may include an input/output pad, a resistor, and a transistor connected in series to a reference voltage. The transistor may have an on-resistance value of about 100 Ω, the resistor may have a resistance of about 200 Ω, and the transmission line may have an impedance of about 50 to 60 Ω. The transistor can be an NMOS transistor or a PMOS transistor, and the reference voltage can be a ground voltage or a source voltage. Also, the input/output pad can be a DQ pad, a DQS pad, or a DM pad. The input/output pad can be connected to a pad of an external memory controller of the memory device using a point-to-point method.

Also, the termination circuit may be electrically coupled to the transmission line by activating a transistor in the termination circuit in response to the control signal. The control signal may be generated by a fuse option or a signal option set in a mode register.

### BRIEF DESCRIPTION OF THE DRAWINGS

FIG. 1 is a schematic diagram illustrating a conventional passive termination circuit on a receiving side of a transmission line;

FIG. 2 is a schematic diagram illustrating a conventional passive termination circuit on a transmitting side of the transmission line;

FIG. 3 is a schematic diagram illustrating an on-die termination circuit according to embodiments of the present invention;

FIG. 4 is a schematic diagram illustrating an on-die termination circuit according to further embodiments of the present invention;

FIG. 5 is a timing diagram for describing operations of the on-die termination circuits shown in FIGS. 3 and 4; and

FIG. 6 is a graph showing simulation test results for the on-die termination circuit shown in FIG. 3.

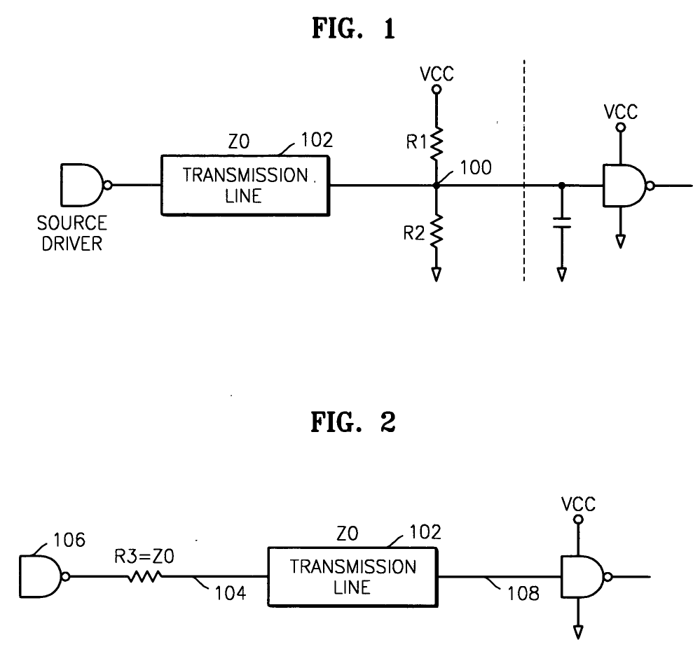

### DETAILED DESCRIPTION OF THE INVENTION

The present invention will now be described more fully with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete and will fully convey the concept of the invention to those skilled in the art. Like numbers refer to like elements throughout.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all technical and scientific terms used herein have the same meaning as commonly understood by one of ordinary skill in the art to which this invention belongs. All publications, patent applications, patents, and other references mentioned herein are incorporated by reference in their entirety.

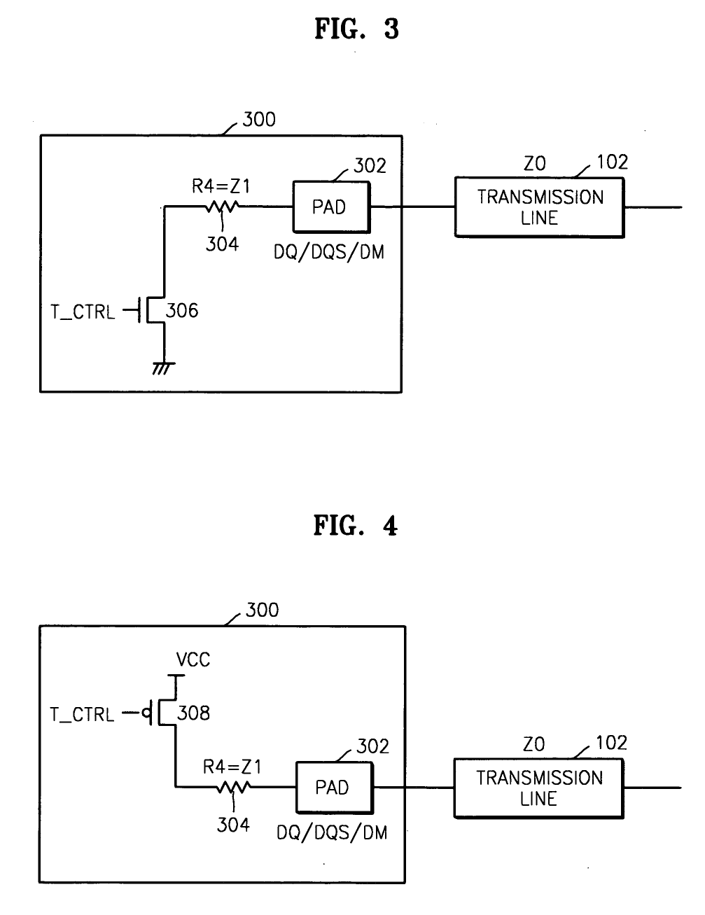

FIG. 3 is a schematic diagram illustrating an on-die termination circuit, according to embodiments of the present invention. Referring to FIG. 3, a memory device 300 includes a pad 302 that is serially connected to a resistor R4 304 and a NMOS transistor 306. The resistance of the resistor R4 304 is about 200 Ω. The pad 302 is preferably a DQ pad, a DQS pad, or a DM pad, which is connected to an external transmission line 102. The pad 302 is connected using a point-to-point method with a pad of a memory controller (not shown) through the transmission line 102. The transmission line 102 preferably has a resistance value of about 50-60 Ω.

The DQ pad is a data input/output pad which allows data to be input to or output from the memory device. The DQS pad allows for loading a data strobe signal, which can be output with data being read from the memory device 300 or input with data being recorded in the memory device 300. The DM pad allows for loading an input mask signal for data writing, which is used to mask a portion of the data being input and thereby reduce the frequency of data writing.

The NMOS transistor 306 is turned on in response to a termination control signal T_CTRL. The termination control signal T_CTRL provides a logic ‘high’ level (active) when the memory device 300 is in an active mode or a write mode, and provides a logic ‘low’ level (non-active) when the memory device 300 is in an idle mode, a power down mode, a refresh mode, and a read mode. The termination control signal T_CTRL may be generated by a fuse option or a signal option set in a mode register MRS. The NMOS transistor 306 has an internal resistance of about 100 Ω when turned on.

Thus, according to embodiments of the present invention, if the memory device 300 is in an active mode or a write mode, the NMOS transistor 306 is turned on in response to a ‘high’ level provided by the termination control signal T_CTRL, so that a total resistance of about 300 Ω exists between the pad 302 and a ground voltage VSS.

According to further embodiments of the present invention, a PMOS transistor 308, which is connected to a source voltage VCC as shown in FIG. 4, can be used instead of the NMOS transistor 306. The PMOS transistor 308 is turned on in response to the termination control signal T_CTRL. The termination control signal T_CTRL may be generated by the fuse option or the signal option set in the mode register MRS, such that the termination control signal T_CTRL provides a logic ‘low’ level (active) when the memory device 300 is in an active mode or a write mode, and provides a logic ‘high’ level (non-active) when the memory device 300 is in an idle mode, a power down mode, a refresh mode, and a read mode. Since the PMOS transistor 308 has an internal resistance of about 100 Ω when turned on, and the resistor R4 304 has a resistance of about 200 Ω, a total resistance of about 300 Ω exists between the pad 302 and the source voltage VCC when the memory device 300 is in an active mode or a write mode.

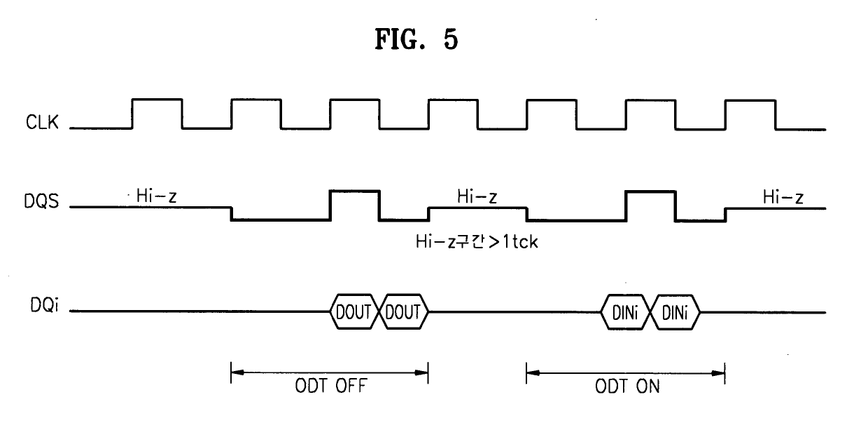

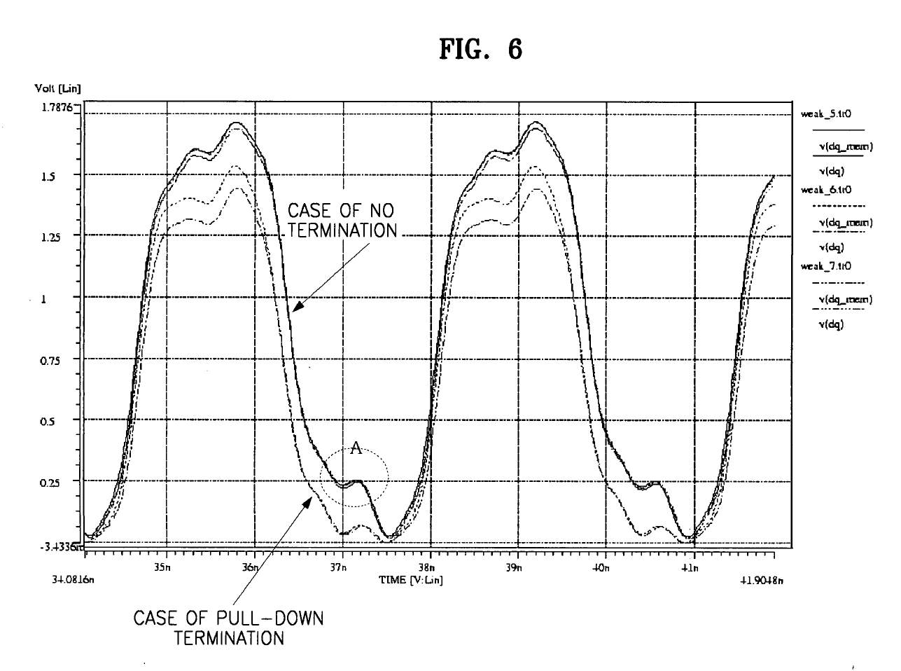

FIG. 5 is a timing diagram for describing operations of the on-die termination circuits shown in FIGS. 3 and 4. Referring to FIG. 5, data is input from or output to a data input/output pad DQi, with synchronization to a clock signal CLK and a data strobe signal DQS. While data is being output from the data input/output pad DQi, the termination circuit is in an ‘off’ state. While data is being input to the data input/output pad DQi, the termination circuit is in an ‘on’ state. Here, the data strobe signal DQS, indicating a data output time interval and a data input time interval, requires a Hi-Z interval of at least one clock cycle between the data output time interval and the data input time interval.

FIG. 6 is a graph illustrating waveforms of signals that are transmitted to a pad 302 via a transmission line 102, according to embodiments of the present invention as shown in FIG. 3. Referring to FIG. 6, in a case of no termination, a “knee” phenomenon (‘A’ portion of FIG. 6) is generated when a signal is received at a logic ‘low’ level. A bouncing signal generated by the knee phenomenon acts as a noise, which may cause an error operation of the memory device 300. Such a knee phenomenon can be removed using a pull-down termination according to embodiments of the present invention. Also, where the pull-down termination is used, a signal transmitted at a logic ‘high’ level becomes relatively lower than the case of no termination. This occurs because of a mismatch between the 50-60 Ω resistance of the transmission line 102 and the 300 Ω total resistance of the termination circuit at the pad 302.

Accordingly, since the on-die termination is activated only when a signal is input to the DQ pad, the DQS pad, or the DM pad, it is possible to reduce power consumption, compared to conventional methods in which termination is always turned on. Also, it is possible to remove the ‘knee’ phenomenon that occurs when a signal is received at a logic ‘low’ level, using a mismatch between the impedance value of the transmission line and that of the termination circuit.

In the drawings and specification, there have been disclosed embodiments according to the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A method of terminating an external transmission line in a memory device having an on-die termination circuit, comprising:
electrically coupling the termination circuit to the transmission line in response to a control signal which indicates that the memory device is in an active mode or a write mode;
wherein the termination circuit has an impedance value that is mismatched with an impedance value of the transmission line.

2. The method of claim 1, wherein electrically coupling the termination circuit to the transmission line comprises:
activating a transistor in the termination circuit to connect the transmission line to a reference voltage in response to the control signal.

3. The method of claim 1, wherein the termination circuit comprises an input/output pad, a resistor, and a transistor connected in series to a reference voltage.

4. The method of claim 2, wherein the transistor is an NMOS transistor, and the reference voltage is a ground voltage.

5. The method of claim 2, wherein the transistor is a PMOS transistor, and the reference voltage is a source voltage.

6. The method of claim 3, wherein the input/output pad is one of a DQ pad, a DQS pad, and a DM pad.

7. The method of claim 3, wherein the transistor has an on-resistance value of about 100 Ω, the resistor has a resistance of about 200 Ω, and the transmission line has an impedance of about 50 to 60 Ω.

8. The method of claim 3, wherein the input/output pad is connected to a pad of an external memory controller of the memory device using a point-to-point method.

9. The method of claim 1, wherein the control signal is generated by a fuse option or a signal option set in a mode register.

10. An integrated circuit memory device, comprising:
a transmission line; and
a termination circuit that is electrically coupled to the transmission line responsive to a control signal which indicates that the memory device is in an active mode or a write mode;
wherein the termination circuit has an impedance value that is mismatched with an impedance value of the transmission line.

11. The device of claim 10, wherein the termination circuit comprises an input/output pad, a resistor, and a transistor connected in series to a reference voltage.

12. The device of claim 11, wherein the termination circuit is electrically coupled to the transmission line by activating the transistor in response to the control signal.

13. The method of claim 11, wherein the transistor is an NMOS transistor, and the reference voltage is a ground voltage.

14. The method of claim 11, wherein the transistor is a PMOS transistor, and the reference voltage is a source voltage.

15. The method of claim 11, wherein the input/output pad is one of a DQ pad, a DQS pad, and a DM pad.

16. The method of claim 11, wherein the transistor has an on-resistance value of about 100 Ω, the resistor has a resistance of about 200 Ω, and the transmission line has an impedance of about 50 to 60 Ω.

17. The method of claim 11, wherein the input/output pad is connected to a pad of an external memory controller of the memory device using a point-to-point method.

18. The method of claim 10, wherein the control signal is generated by a fuse option or a signal option set in a mode register.

19. An on-die termination circuit in a memory device, comprising:
a pad which is connected to an external transmission line;
a resistor having two ends, one end of which is connected in series to the pad; and
an NMOS transistor connected in series between the other end of the resistor and a ground voltage, wherein the transistor has a gate connected to a termination control signal that is activated when the memory device is in an active mode or a write mode.

20. The on-die termination circuit of claim 19, wherein the pad is a data input/output (DQ) pad, a data strobe (DQS) pad, or a data input masking (DM) pad.

21. The on-die termination circuit of claim 19, wherein a mismatch occurs between a sum of a resistance value of the resistor and an on-resistance value of the NMOS transistor as compared to an impedance value of the transmission line when the termination control signal is activated.

22. The on-die termination circuit of claim 21, wherein an impedance value of the transmission line is about 50 to 60 Ω, a resistance value of the resistor is about 200 Ω, and an on-resistance value of the NMOS transistor is about 100 Ω.

23. The on-die termination circuit of claim 19, wherein the termination control signal is set by a fuse option or a signal option set in a mode register.

24. The on-die termination circuit of claim 19, wherein the pad is connected with a pad of an external memory controller of the memory device using a point-to-point method.

25. An on-die termination circuit included in a memory device, comprising:
a pad which is connected to an external transmission line;
a resistor having two ends, one end of which is connected in series to the pad; and
a PMOS transistor connected in series between the other end of the resistor and a voltage source, wherein the transistor has a gate connected to a termination control signal that is activated when the memory device is in an active mode or a write mode.

26. The on-die termination circuit of claim 25, wherein the pad is a data input/output (DQ) pad, a data strobe (DQS) pad, or a data input masking (DM) pad.

27. The on-die termination circuit of claim 25, wherein a mismatch occurs between a sum of a resistance value of the resistor and an on-resistance value of the PMOS transistor as compared to an impedance value of the transmission line when the termination control signal is activated.

28. The on-die termination circuit of claim 25, wherein an impedance value of the transmission line is about 50 to 60 Ω, a resistance value of the resistor is about 200 Ω, and an on-resistance value of the PMOS transistor is about 100 Ω.

29. The on-die termination circuit of claim 25, wherein the termination control signal is set by a fuse option or a signal option set by a mode register.

30. The on-die termination circuit of claim 25, wherein the pad is connected with a pad of an external memory controller of the memory device using a point-to-point method.

31. An on-die termination circuit in a memory device, comprising:
a DQ pad, a DQS pad, and a DM pad, each of which is respectively connected to external transmission lines;
resistors having two ends, one ends of which are connected in series to the pads, respectively; and
NMOS transistors connected in series between the other ends of the resistors and a ground voltage, wherein the transistors have gates connected to termination control signals that are activated when the memory device is in an active mode or a write mode,
wherein a sum of a resistance value of each resistor and an on-resistance value of each NMOS transistor is mismatched with an impedance value of each transmission line.

32. The on-die termination circuit of claim 31, wherein an impedance value of each transmission line is about 50 to 60 Ω, a resistance value of each resistor is about 200 Ω, and an on-resistance value of each NMOS transistor is about 100 Ω.

33. The on-die termination circuit of claim 31, wherein the termination control signals are set by a fuse option or a signal option set in a mode register.

34. An on-die termination circuit in a memory device, comprising:
a DQ pad, a DQS pad, and a DM pad, each of which is connected to transmission lines provided from the external;
resistors having two ends, one ends of which are connected in series to the pads, respectively; and
PMOS transistors connected in series between the other ends of the resistors and a source voltage, wherein the transistors have gates connected to termination control signals that are activated when the memory device is in an active mode or write mode,
wherein a sum of a resistance value of each resistor and an on-resistance value of each PMOS transistor is mismatched with an impedance value of each transmission line.

35. The on-die termination circuit of claim 34, wherein an impedance value of each transmission line is about 50 to 60 Ω, a resistance value of each resistor is about 200 Ω, and an on-resistance value of each PMOS transistor is about 100 Ω.

36. The on-die termination circuit of claim 34, wherein the termination control signals are set by a fuse option or a signal option set in a mode register.

37. A method for terminating a transmission line connected to a pad of a memory device, the method comprising:
activating a termination control signal in response to an active mode or a write mode of the memory device;
turning on an NMOS transistor in response to the termination control signal; and
electrically coupling the pad to a ground voltage through a serially connected resistor and the NMOS transistor,
wherein a sum of a resistance value of the resistor and an on-resistance value of the NMOS transistor is mismatched with an impedance value of the transmission line.

38. The method of claim 37, wherein the pad is a data input/output (DQ) pad, a data strobe (DQS) pad, or a data input masking (DM) pad.

39. The method of claim 37, wherein an impedance value of the transmission line is about 50 to 60 Ω, a resistance value of the resistor is about 200 Ω, and an on-resistance value of the NMOS transistor is about 100 Ω.

40. The method of claim 37, wherein the termination control signal is set by a fuse option or a signal option set in a mode register.

41. The method of claim 37, wherein the pad is connected to a pad of an external memory controller of the memory device using a point-to-point method.

42. A method for terminating a transmission line connected to a pad of a memory device, the method comprising:
activating a termination control signal in response to an active mode or a write mode of the memory device;
turning on a PMOS transistor in response to the termination control signal; and
electrically coupling the pad to a source voltage through a serially connected resistor and the PMOS transistor,
wherein a sum of a resistance value of the resistor and an on-resistance value of the PMOS transistor is mismatched with an impedance value of the transmission line.

43. The method of claim 42, wherein the pad is a data input/output (DQ) pad, a data strobe (DQS) pad, or a data input masking (DM) pad.

44. The method of claim 42, wherein an impedance value of the transmission line is about 50 to 60 Ω, a resistance value of the resistor is about 200 Ω, and an on-resistance value of the PMOS transistor is about 100 Ω.

45. The method of claim 42, wherein the termination control signal is set by a fuse option or a signal option set in a mode register.

46. The method of claim 42, wherein the pad is connected to a pad of an external memory controller of the memory device using a point-to-point method.
